(19) United States
(12) Patent Application Publication
(10) Pub. No.: US 2024/0170475 A1
(43) Pub. Date: May 23, 2024

(54) METHOD FOR MANUFACTURING SEMICONDUCTOR DEVICE, SEMICONDUCTOR DEVICE, INTEGRATED CIRCUIT ELEMENT, AND METHOD FOR MANUFACTURING INTEGRATED CIRCUIT ELEMENT

(71) Applicant: Resonac Corporation, Minato-ku, Tokyo (JP)

(72) Inventors: Shizu FUKUZUMI, Minato-ku, Tokyo (JP); Tomoaki SHIBATA, Minato-ku, Tokyo (JP); Toshiaki SHIRASAKA, Minato-ku, Tokyo (JP)

(21) Appl. No.: 18/552,222

(22) PCT Filed: Mar. 23, 2022
(86) PCT No.: PCT/JP2022/013675

§ 371 Date: Sep. 25, 2023

(30) Foreign Application Priority Data
Mar. 26, 2021 (WO) PCT/JP2021/013032

(51) Int. Cl. H01L 25/00; H01L 21/311; H01L 23/528; H01L 23/532; H01L 25/065

(52) U.S. Cl. CPC H01L 25/50; H01L 21/31116; H01L 23/5283; H01L 23/53295; H01L 25/0657

(57) ABSTRACT

A method for manufacturing a semiconductor device includes providing a first integrated circuit element including a first semiconductor substrate and a first wiring layer, providing a second integrated circuit element including a second semiconductor substrate and a second wiring layer, bonding the first insulating layer and the second insulating layer to each other, and bonding the first electrode and the second electrode to each other. The first insulating layer contains an inorganic insulating material. A plurality of first openings recessed toward the first semiconductor substrate from a bonding surface bonded to the second insulating layer are provided at positions in the first insulating layer in the first wiring layer different from an arrangement position of the first electrode, and the plurality of first openings discontinuously surround the first electrode.

### TECHNICAL FIELD

The present disclosure relates to a method for manufacturing a semiconductor device, a semiconductor device, an integrated circuit element, and a method for manufacturing an integrated circuit element.

### BACKGROUND ART

Patent Literature 1 discloses a hybrid bonding method, which is a three-dimensional integration technique for semiconductors. In this bonding method, an insulating film is formed around electrodes on each bonding surface of a pair of integrated circuit elements (for example, a pair of semiconductor wafers), and the electrodes are bonded to each other and the insulating films are bonded to each other. In addition, a similar technique is disclosed in Patent Literature 2.

### CITATION LIST

### Patent Literature

Patent Literature 1: Specification of U.S. Patent Application Publication No. 2019/0157333
Patent Literature 2: Japanese Unexamined Patent Publication No. 2012-069585

### SUMMARY OF INVENTION

### Technical Problem

In the bonding method described in Patent Literature 1, copper (Cu) is used as the electrodes of the integrated circuit element, and an inorganic insulating film such as silicon dioxide (SiO₂) is used as the insulating film. When bonding the electrodes to each other and bonding the insulating films to each other, each integrated circuit element is heated to, for example, 400° C. for bonding. Then, the bonded integrated circuit elements are cooled to 100° C. to manufacture a semiconductor device. Due to the cooling process after heating, internal stress is accumulated in the integrated circuit element. When the accumulated internal stress is large, cracks may occur in the integrated circuit element (a semiconductor wafer and the like) during cooling. In particular, as the integrated circuit element becomes larger or thinner, cracks are more likely to occur during cooling.

It is an object of the present disclosure to provide a method for manufacturing a semiconductor device, a semiconductor device, an integrated circuit element, and a method for manufacturing an integrated circuit element that can suppress the occurrence of cracks when bonding integrated circuit elements to each other.

### Solution to Problem

One aspect of the present disclosure relates to a method for manufacturing a semiconductor device. The method for manufacturing a semiconductor device includes providing a first integrated circuit element including a first semiconductor substrate having a semiconductor element and a first wiring layer having a first insulating layer and a first electrode and provided on a surface of the first semiconductor substrate; providing a second integrated circuit element including a second semiconductor substrate having a semiconductor element and a second wiring layer having a second insulating layer and a second electrode and provided on a surface of the second semiconductor substrate; bonding the first insulating layer of the first integrated circuit element and the second insulating layer of the second integrated circuit element to each other; and bonding the first electrode of the first integrated circuit element and the second electrode of the second integrated circuit element to each other. The first insulating layer contains an inorganic insulating material. A plurality of first openings recessed toward the first semiconductor substrate from a first bonding surface bonded to the second insulating layer are provided at positions in the first insulating layer different from an arrangement position of the first electrode, and the plurality of first openings discontinuously surround the first electrode.

In this method for manufacturing a semiconductor device, a plurality of first openings are provided at positions in the first insulating layer different from the arrangement position of the first electrode and the plurality of first openings discontinuously surround the first electrode, in the first integrated circuit element. In this case, when bonding the first integrated circuit element to the second integrated circuit element, even if internal stress is accumulated in the first integrated circuit element or the second integrated circuit element due to heating, the internal stress is released by the plurality of first openings during cooling. In particular, such accumulation of internal stress is likely to occur between the first insulating layer and the first electrode, which have different coefficients of thermal expansion. However, the internal stress can be effectively released by the plurality of first openings that discontinuously surround the first electrode. That is, according to this manufacturing method, internal stress can be reduced by forming a stress-free place in the semiconductor device to be manufactured. As a result, according to this method for manufacturing a semiconductor device, it is possible to suppress the occurrence of cracks due to cooling.

In the method for manufacturing a semiconductor device described above, the plurality of first openings may be provided such that the first electrode is not exposed to each side surface of the plurality of first openings. In this case, the first electrode is covered with the first insulating layer without being exposed to the outside except for the connection end on the surface side. Therefore, the influence of the external environment on the first electrode is reduced, and thus it is possible to improve the reliability of the first electrode.

In the method for manufacturing a semiconductor device described above, the plurality of first openings may be provided such that the first semiconductor substrate is not exposed to each bottom surface of the plurality of first openings. In this case, the first semiconductor substrate is covered with the first insulating layer without a surface for connection with the first electrode being exposed to the outside. Therefore, the influence of the external environment on the connection region between the first semiconductor substrate and the first electrode is reduced, and thus it is possible to improve the reliability of connection between the first semiconductor substrate and the first electrode.

In the method for manufacturing a semiconductor device described above, each of the plurality of first openings may have an opening shape closed in a planar direction of the first insulating layer. In this case, it is difficult for factors affecting the semiconductor device to enter the plurality of first openings in the manufactured semiconductor device, that is, the inside of the semiconductor device. Therefore, the influence of the external environment on the semiconductor device is reduced, and thus it is possible to manufacture a highly reliable semiconductor device.

In the method for manufacturing a semiconductor device described above, a width in its short-length direction or a diameter of each of the plurality of first openings may be smaller than a width in its short-length direction or a diameter of the first electrode. In this case, the area of the plurality of first openings formed in the first insulating layer can be reduced, and accordingly, the region of the first insulating layer used for bonding with the second insulating layer can be widened. As a result, the bonding between the first integrated circuit element and the second integrated circuit element can be made more reliable. In the method for manufacturing a semiconductor device described above, a ratio of a total area of the plurality of first openings to a total area of the first insulating layer in the planar direction may be 65% or less. In this case, the bonding between the first integrated circuit element and the second integrated circuit element can be made more reliable.

In the method for manufacturing a semiconductor device described above, the plurality of first openings may be formed by dry-etching the first insulating layer of the first integrated circuit element. In this case, fine first openings can be formed quickly.

In the method for manufacturing a semiconductor device described above, the second insulating layer may contain an inorganic insulating material. A plurality of second openings recessed toward the second semiconductor substrate from a second bonding surface bonded to the first insulating layer may be provided at positions in the second insulating layer different from an arrangement position of the second electrode, and the plurality of second openings may discontinuously surround the second electrode. In this case, when bonding the first integrated circuit element to the second integrated circuit element, even if internal stress is accumulated in the first integrated circuit element or the second integrated circuit element due to heating, the internal stress is released not only by the first openings but also by the second openings. As a result, according to this method for manufacturing a semiconductor device, it is possible to further suppress the occurrence of cracks due to cooling.

In the method for manufacturing a semiconductor device described above, the inorganic insulating material contained in at least one insulating layer of the first insulating layer and the second insulating layer may be silicon dioxide, silicon nitride, or silicon oxynitride. In this case, a wiring layer having finer first electrodes can be formed. In addition, finer openings can be formed.

Another aspect of the present disclosure relates to a semiconductor device. The semiconductor device includes: a first integrated circuit element including a first semiconductor substrate having a semiconductor element and a first wiring layer having a first insulating layer and a first electrode and provided on a surface of the first semiconductor substrate; and a second integrated circuit element including a second semiconductor substrate having a semiconductor element and a second wiring layer having a second insulating layer and a second electrode and provided on a surface of the second semiconductor substrate. The first insulating layer of the first integrated circuit element and the second insulating layer of the second integrated circuit element are bonded to each other. The first electrode of the first integrated circuit element and the second electrode of the second integrated circuit element are bonded to each other. The first insulating layer contains an inorganic insulating material. A plurality of first openings recessed toward the first semiconductor substrate from a first bonding surface bonded to the second insulating layer are provided at positions in the first insulating layer different from an arrangement position of the first electrode, and the plurality of first openings discontinuously surround the first electrode.

In the semiconductor device described above, in the first integrated circuit element, a plurality of first openings are provided at positions in the first insulating layer different from the arrangement position of the first electrode. In this case, the internal stress is released by the first openings in the same manner as described above. As a result, the occurrence of cracks in the semiconductor device is suppressed.

Still another aspect of the present disclosure relates to an integrated circuit element to be bonded to another integrated circuit element to manufacture a semiconductor device. The integrated circuit element includes: a semiconductor substrate having a first surface and a second surface, a semiconductor element being formed at least on the first surface or inside the semiconductor substrate; and a wiring layer provided on the second surface of the semiconductor substrate. The wiring layer includes: an inorganic insulating layer provided on the second surface of the semiconductor substrate; and an electrode that is electrically connected to the semiconductor element of the semiconductor substrate and passes through the inorganic insulating layer to be exposed to an outside from the inorganic insulating layer. A plurality of openings recessed toward the semiconductor substrate are provided at positions in the inorganic insulating layer different from an arrangement position of the electrode, and the plurality of openings discontinuously surround the electrode.

In the integrated circuit element described above, a plurality of openings are provided at positions in the inorganic insulating layer different from the arrangement position of the electrode. In this case, by manufacturing a semiconductor device using the integrated circuit element, the internal stress of the semiconductor device is released by the openings as described above. As a result, the occurrence of cracks in the semiconductor device is suppressed.

Still another aspect of the present disclosure relates to a method for manufacturing an integrated circuit element to be bonded to another integrated circuit element to manufacture a semiconductor device. The method for manufacturing an integrated circuit element includes providing a semiconductor substrate having a first surface and a second surface, a semiconductor element being formed at least on the first surface or inside the semiconductor substrate; and forming a wiring layer on the second surface of the semiconductor substrate. The forming of the wiring layer includes forming an inorganic insulating layer on the second surface of the semiconductor substrate; forming an electrode passing through the inorganic insulating layer so as to be electrically connected to the semiconductor element; and forming a plurality of openings recessed toward the semiconductor substrate at positions in the inorganic insulating layer different from an arrangement position of the electrode, the plurality of openings discontinuously surrounding the electrode.

According to the method for manufacturing an integrated circuit element described above, a plurality of openings are formed at positions in the inorganic insulating layer different from the arrangement position of the electrode. In this case, by using the integrated circuit element manufactured by this method, the internal stress of the semiconductor device is released by a plurality of openings as described above. As a result, the occurrence of cracks in the semiconductor device is suppressed.

In the method for manufacturing an integrated circuit element described above, in the forming of the opening, the openings may be formed by dry-etching the inorganic insulating layer. In this case, fine openings can be formed quickly.

In the method for manufacturing an integrated circuit element described above, the forming of the openings may be performed after the forming of the electrode. In this case, it is possible to form a plurality of openings with different heights from the electrode.

In the method for manufacturing an integrated circuit element described above, the forming of the electrode may be performed after the forming of the openings.

### Advantageous Effects of Invention

According to one aspect of the present disclosure, it is possible to suppress the occurrence of cracks when bonding integrated circuit elements to each other.

### BRIEF DESCRIPTION OF DRAWINGS

FIG. 1 is a cross-sectional view showing an example of a semiconductor device manufactured by using a method according to an embodiment of the present disclosure.

FIG. 2 is a traverse cross-sectional view showing a part (upper portion) of the semiconductor device shown in FIG. 1.

FIGS. 3A to 3C are plan views showing modification examples of the shape of an opening.

FIGS. 4A to 4D are cross-sectional views sequentially showing steps of a method for manufacturing an integrated circuit element according to an embodiment.

FIGS. 5A to 5D are cross-sectional views sequentially showing steps of a method for manufacturing an integrated circuit element according to another embodiment.

FIG. 6 is a cross-sectional view showing a method for manufacturing the semiconductor device shown in FIG. 1.

### DESCRIPTION OF EMBODIMENTS

Hereinafter, several embodiments of the present disclosure will be described in detail with reference to the diagrams as necessary. In the following description, the same or equivalent portions are denoted by the same reference numerals, and repeated descriptions thereof will be omitted. It is assumed that the positional relationship such as up, down, left, and right is based on the positional relationship shown in the diagrams unless otherwise specified. When terms such as “left”, “right”, “front”, “rear”, “top”, “bottom”, “upper”, and “lower” are used in the description and claims of this specification, these are intended to be illustrative and do not necessarily mean that these are in the relative position at all times. The dimensional ratio of each diagram is not limited to the ratio shown in the diagram.

In this specification, the term “layer” includes not only a structure having a shape formed on the entire surface but also a structure having a shape partially formed when observed as a plan view. In this specification, the term “step” includes not only an independent step but also a step whose intended action is achieved even if the step cannot be clearly distinguished from other steps. The numerical range indicated by using “to” indicates a range including the numerical values before and after “to” as the minimum and maximum values, respectively. In the numerical ranges described stepwise in this specification, the upper limit value or lower limit value described in one numerical range may be replaced with the upper limit value or lower limit value of the numerical range described in another stepwise description. In the numerical ranges described in this specification, the upper limit value or lower limit value of each numerical range may be replaced with the values shown in the examples.

(Structure of Semiconductor Device)

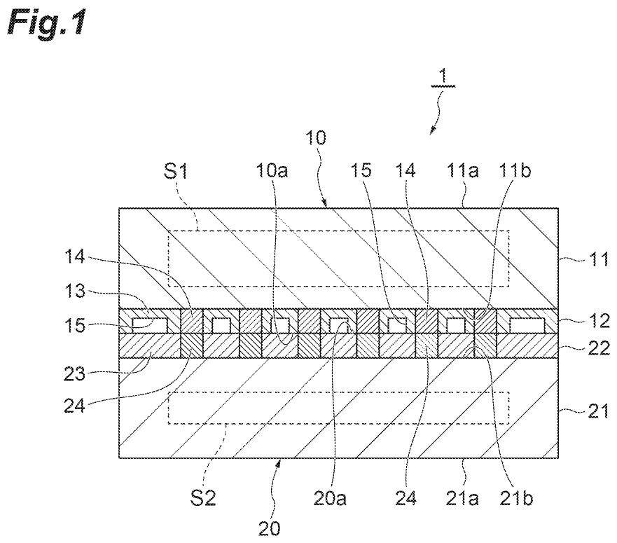

FIG. 1 is a cross-sectional view schematically showing an example of a semiconductor device manufactured by using a manufacturing method according to the present embodiment. As shown in FIG. 1, a semiconductor device 1 includes a first integrated circuit element 10 and a second integrated circuit element 20. The first integrated circuit element 10 includes a first semiconductor substrate 11 and a first wiring layer 12 provided on the first semiconductor substrate 11. The second integrated circuit element 20 includes a second semiconductor substrate 21 and a second wiring layer 22 provided on the second semiconductor substrate 21. In the semiconductor device 1, the first wiring layer 12 of the first integrated circuit element 10 and the second wiring layer 22 of the second integrated circuit element 20 are bonded to each other through a bonding surface 10a (first bonding surface) and a bonding surface 20a (second bonding surface) to form the semiconductor device 1.

The first semiconductor substrate 11 and the second semiconductor substrate 21 are semiconductor wafers in which a plurality of semiconductor elements S1 and S2 forming functional circuits corresponding to semiconductor chips, such as Large scale Integrated Circuit (LSI) chips or Complementary Metal Oxide Semiconductor (CMOS) sensors, are provided. The first semiconductor substrate 11 has a first surface 11a and a second surface 11b (a surface) on the opposite side, and is configured such that the plurality of semiconductor elements S1 described above are provided on the first surface 11a or inside the substrate. The second semiconductor substrate 21 has a first surface 21a and a second surface 21b on the opposite side, and is configured such that the plurality of semiconductor elements S2 described above are provided on the first surface 21a or inside the substrate.

The first wiring layer 12 and the second wiring layer 22 are layers in which a plurality of electrodes electrically connected to the plurality of semiconductor elements S1 and S2 included in the first semiconductor substrate 11 and the second semiconductor substrate 21 adjacent to each other are provided in insulating films and from which one end of each electrode is exposed to the outside. The first wiring layer 12 includes an inorganic insulating layer 13 (first insulating layer), a plurality of electrodes 14 (first electrodes), and a plurality of openings 15 (a plurality of first openings). The second wiring layer 22 includes an inorganic insulating layer 23 (second insulating layer) and a plurality of electrodes 24 (second electrodes). In the example shown in FIG. 1, the openings 15 provided in the first wiring layer 12 is not provided in the second wiring layer 22. However, a plurality of similar openings may be provided in the second wiring layer 22. In the semiconductor device 1, the inorganic insulating layer 13 of the first wiring layer 12 and the inorganic insulating layer 23 of the second wiring layer 22 are bonded to each other, and each electrode 14 of the first wiring layer 12 and each electrode 24 of the second wiring layer 22 are bonded to each other.

The inorganic insulating layer 13 is an insulating layer provided on the second surface 11b of the first semiconductor substrate 11. The inorganic insulating layer 13 is formed of an inorganic material, such as silicon dioxide (SiO₂), silicon nitride (SiN), or silicon oxynitride (SiON). The inorganic insulating layer 13 may include a plurality of insulating layers (for example, three or more inorganic insulating layers).

Each of the electrodes 14 is an electrode that is electrically connected to the semiconductor element S1 of the first semiconductor substrate 11 and passes through the inorganic insulating layer 13. The electrode 14 is formed of a conductive metal, such as copper (Cu), and passes through the inorganic insulating layer 13. The electrode 14 may be configured such that its diameter increases stepwise from the first semiconductor substrate 11 toward the bonding surface 10a. The diameter of the electrode 14 may be, for example, 0.005 μm or more and 20 μm or less.

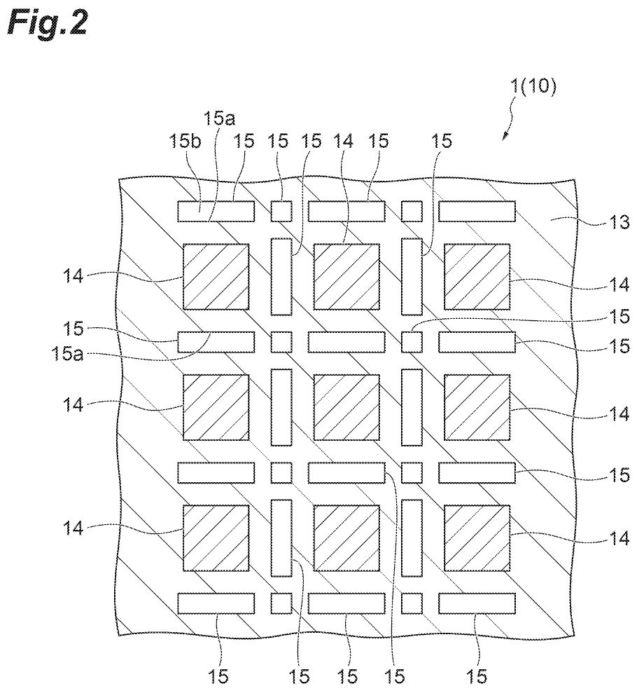

Each of the plurality of openings 15 is a recessed portion recessed from the bonding surface 10a of the inorganic insulating layer 13 toward the first semiconductor substrate 11, and forms a void inside the semiconductor device 1. By providing the void inside the semiconductor device 1, the internal stress accumulated in the semiconductor device 1 when bonding the first integrated circuit element 10 and the second integrated circuit element 20 to each other, which will be described later, is released. In addition, the opening 15 may have a function of releasing an external force applied from the outside after the semiconductor device 1 is manufactured. Each of the openings 15 is provided between the electrodes 14 or outside the electrode 14. For example, as shown in FIG. 2, the openings 15 are formed along the arrangement of the electrodes 14, and are provided so as to surround the electrodes 14 discontinuously. The opening 15 is provided at a position in the inorganic insulating layer 13 different from the arrangement position of each electrode 14, and is spaced apart from the electrode 14. Therefore, the electrode 14 is not exposed to a side surface 15a of the opening 15. In addition, a bottom surface 15b of the opening 15 is formed so as to be spaced apart from the first semiconductor substrate 11. Therefore, the second surface 11b of the first semiconductor substrate 11 is not exposed to the bottom surface 15b of the opening 15.

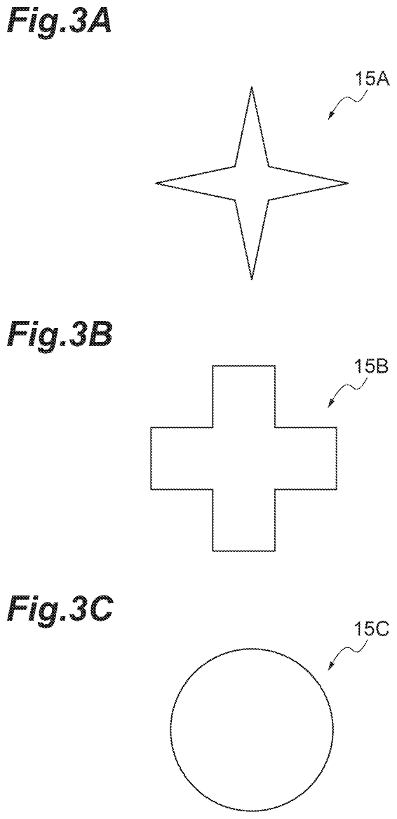

As shown in FIG. 2, each of the openings 15 has an opening shape, such as a rectangular shape, that is closed in the planar direction of the inorganic insulating layer 13. The shape of the opening 15 in the planar direction is not limited to the rectangular shape shown in FIG. 2. For example, a star (for example, four-pointed star)-shaped opening 15A shown in FIG. 3A may be used, a cross-shaped opening 15B shown in FIG. 3B may be used, or a circular or elliptical opening 15C shown in FIG. 3C may be used. The width in its short-length direction or the diameter of each of the openings 15 and 15A to 15C may be smaller than the width in its short-length direction or the diameter of each electrode 14. It is preferable that the ratio of the total area of the openings 15 to the total area of the inorganic insulating layer 13 in the planar direction is 65% or less. In this case, bonding between the first integrated circuit element 10 and the second integrated circuit element 20 is not hindered by the provision of the openings 15. As a result, reliable bonding can be performed.

As shown in FIG. 1, the inorganic insulating layer 23 is an insulating layer provided on the second surface 21b of the second semiconductor substrate 21. Similar to the inorganic insulating layer 13, the inorganic insulating layer 23 is formed of an inorganic material, such as silicon dioxide (SiO₂), silicon nitride (SiN), or silicon oxynitride (SiON). It is preferable that the inorganic insulating layer 23 is formed of the same inorganic insulating material as the inorganic insulating layer 13. The inorganic insulating layer 23 may include a plurality of insulating layers (for example, three or more inorganic insulating layers).

The electrode 24 is an electrode that is electrically connected to the semiconductor element S2 of the second semiconductor substrate 21 and passes through the inorganic insulating layer 23. The electrode 24 is formed of a conductive metal, such as copper (Cu), and passes through the inorganic insulating layer 23. The electrode 24 may be configured such that its diameter increases stepwise from the second semiconductor substrate 21 toward the bonding surface 20a. The diameter of the electrode 24 may be, for example, 0.005 μm or more and 20 μm or less. The electrode 24 is bonded to the electrode 14 so as to be electrically and mechanically connected thereto.

(Method for Manufacturing Semiconductor Device)

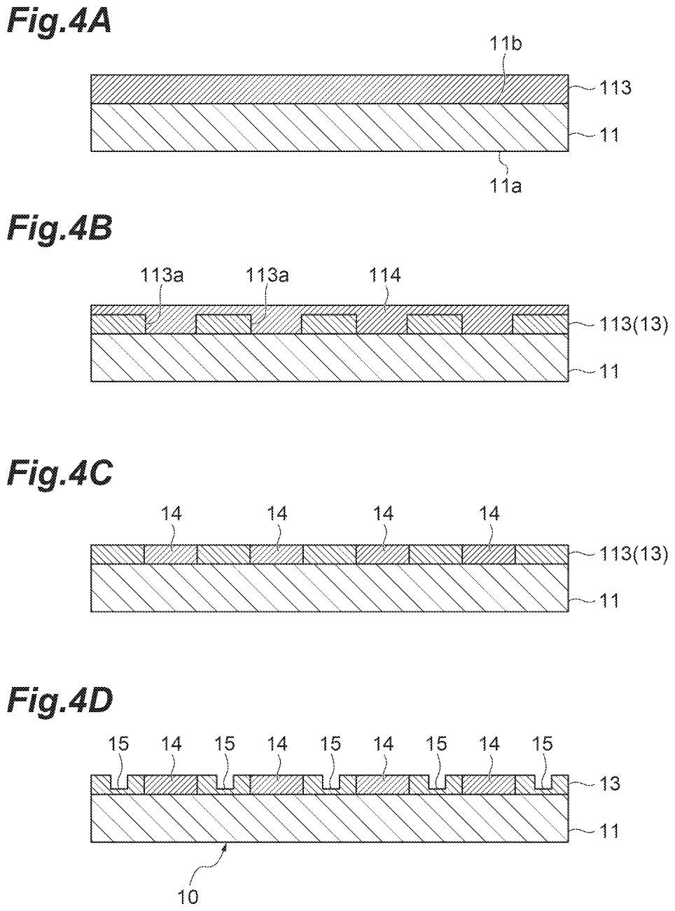

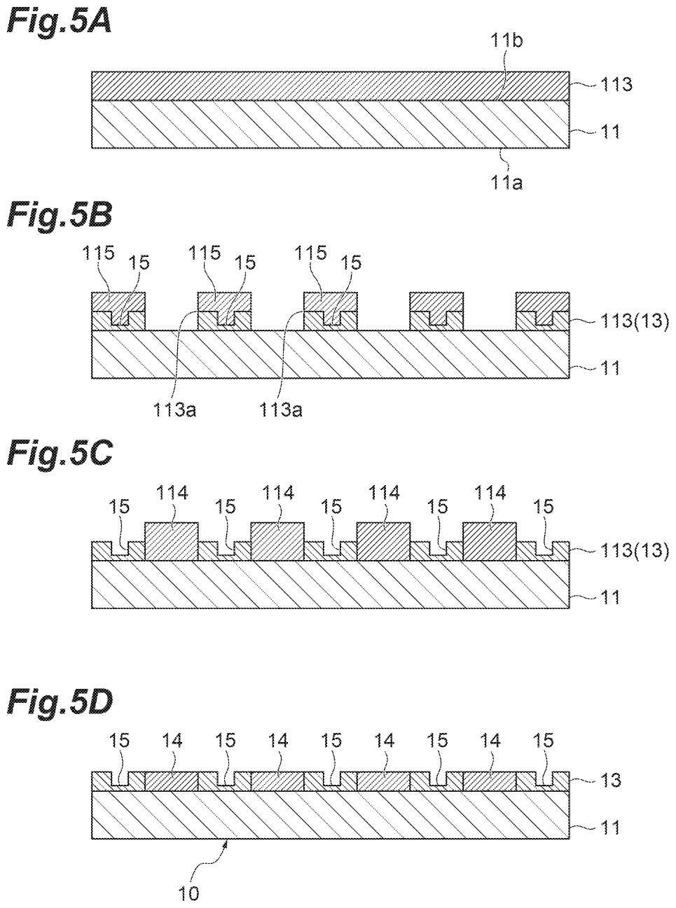

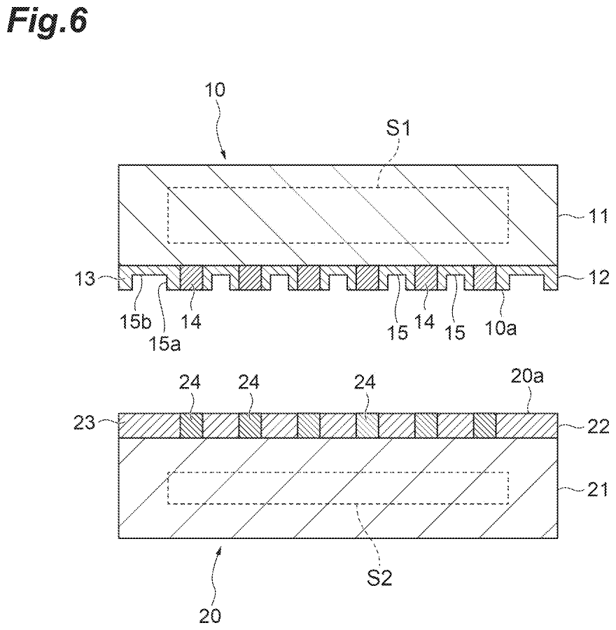

Next, a method for manufacturing the semiconductor device 1 will be described with reference to FIGS. 4A to 4C to FIG. 6. FIGS. 4A to 4D are cross-sectional views showing a method for manufacturing the first integrated circuit element 10 used when manufacturing the semiconductor device 1. FIGS. 5A to 5C are cross-sectional views showing another method for manufacturing the first integrated circuit element 10. FIG. 6 is a cross-sectional view showing a method for manufacturing the semiconductor device 1 from the first integrated circuit element 10 and the second integrated circuit element 20.

The semiconductor device 1 can be manufactured, for example, through the following steps (a) to (d).
(a) Step of preparing (providing) the first integrated circuit element 10 (see FIGS. 4A to 4D and FIGS. 5A to 5D).
(b) Step of preparing (providing) the second integrated circuit element 20 (see FIG. 6).
(c) Step of bonding the inorganic insulating layer 13 of the first integrated circuit element 10 and the inorganic insulating layer 23 of the second integrated circuit element 20 to each other (see FIG. 6).
(d) Step of bonding the electrodes 14 of the first integrated circuit element 10 and the electrodes 24 of the second integrated circuit element 20 to each other (see FIG. 6).

[Step (a)]

Step (a) is a step of preparing the first integrated circuit element 10 including the first semiconductor substrate 11 having a plurality of semiconductor elements and the first wiring layer 12 provided on the second surface 11b of the first semiconductor substrate 11. In step (a), as shown in FIG. 4A, first, an inorganic insulating layer 113 is formed on the second surface 11b of the first semiconductor substrate 11 formed of silicon or the like in which functional circuits are formed. On the first surface 11a of the first semiconductor substrate 11 and inside the first semiconductor substrate 11, a plurality of semiconductor elements S1 (not shown in FIGS. 4A to 4D) are already formed. The inorganic insulating layer 113 is formed of an inorganic material, such as silicon dioxide (SiO₂), and has a thickness of 0.01 μm or more and 10 μm or less. Then, as shown in FIG. 4B, a plurality of grooves or holes 113a are provided in the inorganic insulating layer 113 by using, for example, a damascene method, and a metal 114 such as copper is embedded in each groove or hole 113a by using a method such as electroplating, sputtering, or chemical vapor deposition (CVD). When forming the plurality of grooves or holes 113a, predetermined portions of the inorganic insulating layer 113 are processed by dry etching. Thereafter, as shown in FIG. 4C, the metal 114 is polished by chemical mechanical polishing (CMP) to form a plurality of electrodes 14. The width or diameter of the electrode 14 is, for example, 0.01 μm or more and 10 μm or less. Thereafter, a resist (not shown) is formed on the wiring layer formed by the inorganic insulating layer 113 and the electrodes 14 so as to exclude regions where the openings 15 are formed, and a plurality of openings 15 are formed by dry etching as shown in FIG. 4D. Thereafter, the resist is removed to acquire the first integrated circuit element 10.

The first integrated circuit element 10 may be formed by using another method shown in FIGS. 5A to 5D. As shown in FIG. 5A, first, the inorganic insulating layer 113 is formed on the second surface 11b of the first semiconductor substrate 11 formed of silicon or the like in which functional circuits are formed. On the first surface 11a of the first semiconductor substrate 11 and inside the first semiconductor substrate 11, a plurality of semiconductor elements S1 (not shown in FIGS. 5A to 5D) are already formed. The inorganic insulating layer 113 is formed of, for example, an inorganic material, such as silicon dioxide (SiO₂), and has a thickness of 0.01 μm or more and 10 μm or less. Then, as shown in FIG. 5B, the openings 15 are formed in the inorganic insulating layer 113 by dry etching, and a resist 115 is provided on the opening 15. In addition, grooves or the holes 113a for forming the electrodes 14 are formed by sputtering, and the resist 115 is removed. Thereafter, as shown in FIG. 5C, electrodes 114 are formed in the grooves or the holes 113a by electrolytic copper plating. Then, as shown in FIG. 5D, the electrodes 114 and the like are polished by using a chemical mechanical polishing method (CMP method) to form a plurality of electrodes 14, thereby obtaining the first integrated circuit element 10.

[Step (b)]

Step (b) is a step of preparing (providing) the second integrated circuit element 20 including the second semiconductor substrate 21 having a plurality of semiconductor elements and the second wiring layer 22 provided on the second surface of the second semiconductor substrate 21. In step (b), as in step (a), the inorganic insulating layer 23 is formed on the second surface 21b of the second semiconductor substrate 21 formed of silicon or the like, a plurality of grooves or holes are provided in the inorganic insulating layer 23 by using, for example, a damascene method, and a metal such as copper is embedded in each groove or hole by using a method such as electroplating, sputtering, or chemical vapor deposition (CVD), thereby forming the electrodes 24 (for example, see FIGS. 4A to 4C). The inorganic insulating layer 23 may be provided after the electrodes 24 are provided. In the manufacture of the semiconductor device 1 shown in FIG. 1, no opening is provided in the second integrated circuit element 20. However, in the case of providing an opening corresponding to the opening 15, the method shown in FIGS. 4A to 4D or FIGS. 5A to 5D can be used.

[Step (c)]

Step (c) is a step of bonding the inorganic insulating layer 13 of the first integrated circuit element 10 and the inorganic insulating layer 23 of the second integrated circuit element 20 to each other. In step (c), organic matter or metal oxide adhering to the bonding surface 10a of the first integrated circuit element 10 and the bonding surface 20a of the second integrated circuit element 20 is removed. Then, as shown in FIG. 6, the bonding surface 10a of the first integrated circuit element 10 is made to face the bonding surface 20a of the second integrated circuit element 20, and alignment between each electrode 14 of the first integrated circuit element 10 and each electrode 24 of the second integrated circuit element 20 is performed. At this alignment stage, the inorganic insulating layer 13 of the first integrated circuit element 10 and the inorganic insulating layer 23 of the second integrated circuit element 20 are spaced apart from each other and are not bonded to each other (however, the electrodes 14 and 24 are aligned). After the end of the alignment, the inorganic insulating layer 13 of the first integrated circuit element 10 and the inorganic insulating layer 23 of the second integrated circuit element 20 are bonded to each other. At this time, the inorganic insulating layer 13 of the first integrated circuit element 10 and the inorganic insulating layer 23 of the second integrated circuit element 20 may be uniformly heated and then bonded to each other. The heating temperature when bonding the inorganic insulating layer 13 and the inorganic insulating layer 23 to each other may be, for example, 25° C. or higher and 800° C. or lower, and the pressure may be 0.1 MPa or higher and 10 MPa or lower. It is preferable that the temperature difference between the inorganic insulating layer 13 and the inorganic insulating layer 23 during bonding is, for example, 10° C. or lower. By heating and bonding at such a uniform temperature, the inorganic insulating layer 13 and the inorganic insulating layer 23 are bonded to each other to form an insulating bonding portion, so that the first integrated circuit element 10 and the second integrated circuit element 20 are mechanically strongly attached to each other. Since heating and bonding is performed at a uniform temperature, it is difficult for misalignment or the like to occur at the bonding portion. Therefore, high-precision bonding can be performed.

[Step (d)]

Step (d) is a step of bonding the electrodes 14 of the first integrated circuit element 10 and the electrodes 24 of the second integrated circuit element 20 to each other. In step (d), when the bonding between the inorganic insulating layer 13 and the inorganic insulating layer 23 in step (c) ends, predetermined heat or pressure or both are applied to bond the electrodes 14 of the first integrated circuit element 10 and the electrodes 24 of the second integrated circuit element 20 to each other. When the electrodes 14 and 24 are formed of copper, the heating temperature in step (d) is 150° C. or higher and 400° C. or lower or may be 200° C. or higher and 300° C. or lower, and the pressure may be 0.1 MPa or higher and 10 MPa or lower. By such a bonding process, the electrode 14 and the electrode 24 corresponding to the electrode 14 are bonded to each other to form an electrode bonding portion, so that the electrode 14 and the electrode 24 are mechanically and electrically strongly bonded to each other. The electrode bonding in step (d) is performed after the bonding in step (c) as an example, but may be performed simultaneously with the bonding in step (c).

When the bonding between the first integrated circuit element 10 and the second integrated circuit element 20 in steps (c) and (d) ends, the semiconductor device 1 can be obtained. Individual semiconductor devices can be obtained by singulating the semiconductor device 1 with a cutting means such as dicing. As a method for singulating the semiconductor device 1, for example, plasma dicing, stealth dicing, or laser dicing can be used.

As described above, according to the method for manufacturing a semiconductor device according to the present embodiment, in the first integrated circuit element 10, the openings 15 are provided at positions in the inorganic insulating layer 13 different from the arrangement position of the electrodes 14, and a plurality of openings 15 discontinuously surround the electrode 14. In this case, when bonding the first integrated circuit element 10 to the second integrated circuit element 20, even if internal stress is accumulated in the first integrated circuit element 10 or the second integrated circuit element 20 due to heating, the internal stress is released by the plurality of openings 15 during cooling. In particular, such accumulation of internal stress is likely to occur between the inorganic insulating layer 13 and the electrodes 14, which have different coefficients of thermal expansion. However, the internal stress can be effectively released by the plurality of openings 15 that discontinuously surround the electrode 14. That is, according to this manufacturing method, internal stress can be reduced by forming a stress-free place in the semiconductor device 1 to be manufactured. As a result, according to this method for manufacturing a semiconductor device, it is possible to suppress the occurrence of cracks due to cooling.

In the method for manufacturing a semiconductor device according to the present embodiment, the plurality of openings 15 are provided so that the electrode 14 is not exposed to each side surface 15a of the plurality of openings 15. For this reason, the electrode 14 is covered with the inorganic insulating layer 13 without being exposed to the outside except for the connection end on the surface side. Therefore, since the influence of the external environment on the electrode 14 is reduced, it is possible to improve the reliability of the electrode 14.

In the method for manufacturing a semiconductor device according to the present embodiment, the plurality of openings 15 are provided so that the first semiconductor substrate 11 is not exposed to each bottom surface 15b of the plurality of openings 15. For this reason, the first semiconductor substrate 11 is covered with the inorganic insulating layer 13 without a surface for connection with the electrode 14 being exposed to the outside. Therefore, since the influence of the external environment on the connection regions between the first semiconductor substrate 11 and the electrodes 14 are reduced, it is possible to improve the reliability of connection between the first semiconductor substrate 11 and the electrodes 14.

In the method for manufacturing a semiconductor device according to the present embodiment, each of the plurality of openings 15 has an opening shape that is closed in the planar direction of the inorganic insulating layer 13. For this reason, it is difficult for factors affecting the semiconductor device 1 to enter the opening 15 in the manufactured semiconductor device 1, that is, the inside of the semiconductor device 1. Therefore, since the influence of the external environment on the semiconductor device 1 is reduced, it is possible to manufacture a highly reliable semiconductor device.

In the method for manufacturing a semiconductor device according to the present embodiment, the width its short-length direction or the diameter of each of the plurality of openings 15 in is smaller than the width in its short-length direction or the diameter of the electrode 14. For this reason, the area of the plurality of openings 15 formed in the inorganic insulating layer 13 can be reduced, and accordingly, the region of the inorganic insulating layer 13 used for bonding with the inorganic insulating layer 23 can be widened. As a result, the bonding between the first integrated circuit element 10 and the second integrated circuit element 20 can be made more reliable.

In the method for manufacturing a semiconductor device according to the present embodiment, the plurality of openings 15 are formed by dry-etching the inorganic insulating layer 13 of the first integrated circuit element 10. According to this method, it is possible to quickly form the fine openings 15.

In the method for manufacturing a semiconductor device according to the present embodiment, the inorganic insulating material forming the inorganic insulating layer 13 and the inorganic insulating layer 23 is silicon dioxide, silicon nitride, or silicon oxynitride. As a result, it is possible to form each wiring layer having the finer electrodes 14 and 24, and it is possible to form the finer openings 15 and the like.

In the method for manufacturing a semiconductor device according to the present embodiment, another plurality of openings (a plurality of second openings) recessed from the bonding surface 20a toward the second semiconductor substrate 21 may be provided at positions in the inorganic insulating layer 23 different from the arrangement positions of the electrodes 24. In this case, when bonding the first integrated circuit element 10 to the second integrated circuit element 20, even if internal stress is accumulated in the first integrated circuit element 10 or the second integrated circuit element 20 due to heating, the internal stress is released not only by the openings 15 but also by another opening. As a result, according to this method for manufacturing a semiconductor device, it is possible to further suppress the occurrence of cracks due to cooling.

While the embodiments of the present disclosure have been described above in detail, the present invention is not limited to the above embodiments. For example, although the case of applying the present invention to hybrid bonding in Wafer to Wafer (W2 W) is illustrated in the above embodiments, the present invention may be applied to Chip to Chip (C2C) or Chip to Wafer (C2 W).

### REFERENCE SIGNS LIST

1: semiconductor device, 10: first integrated circuit element, 10a: bonding surface (first bonding surface), 11: first semiconductor substrate, 11a: first surface, 11b: second surface, 12: first wiring layer, 13: inorganic insulating layer (first insulating layer), 14: electrode (first electrode), 15, 15A to 15C: opening (first opening), 15a: side surface, 15b: bottom surface, 20: second integrated circuit element, 20a: bonding surface (second bonding surface), 21: second semiconductor substrate, 22: second wiring layer, 23: inorganic insulating layer (second insulating layer), 24: electrode (second electrode).

1. A method for manufacturing a semiconductor device, comprising:
providing a first integrated circuit element including a first semiconductor substrate having a semiconductor element and a first wiring layer having a first insulating layer and a first electrode, the first wiring layer being provided on a surface of the first semiconductor substrate;
providing a second integrated circuit element including a second semiconductor substrate having a semiconductor element and a second wiring layer having a second insulating layer and a second electrode, the second wiring layer being provided on a surface of the second semiconductor substrate;
bonding the first insulating layer of the first integrated circuit element and the second insulating layer of the second integrated circuit element to each other; and
bonding the first electrode of the first integrated circuit element and the second electrode of the second integrated circuit element to each other,
wherein the first insulating layer contains an inorganic insulating material, and
wherein a plurality of first openings recessed toward the first semiconductor substrate from a first bonding surface bonded to the second insulating layer are provided at positions in the first insulating layer different from an arrangement position of the first electrode, and the plurality of first openings discontinuously surround the first electrode.

2. The method for manufacturing a semiconductor device according to claim 1,
wherein the plurality of first openings are provided such that the first electrode is not exposed to each side surface of the plurality of first openings.

3. The method for manufacturing a semiconductor device according to claim 1,
wherein the plurality of first openings are provided such that the first semiconductor substrate is not exposed to each bottom surface of the plurality of first openings.

4. The method for manufacturing a semiconductor device according to claim 1,
wherein each of the plurality of first openings has an opening shape closed in a planar direction of the first insulating layer.

5. The method for manufacturing a semiconductor device according to claim 1,
wherein a width in its short-length direction or a diameter of each of the plurality of first openings is smaller than a width in its short-length direction or a diameter of the first electrode.

6. The method for manufacturing a semiconductor device according to claim 1,
wherein a ratio of a total area of the plurality of first openings to a total area of the first insulating layer in the planar direction is 65% or less.

7. The method for manufacturing a semiconductor device according to claim 1,
wherein the plurality of first openings are formed by dry-etching the first insulating layer of the first integrated circuit element.

8. The method for manufacturing a semiconductor device according to claim 1,
wherein the second insulating layer contains an inorganic insulating material, and
wherein a plurality of second openings recessed toward the second semiconductor substrate from a second bonding surface bonded to the first insulating layer are provided at positions in the second insulating layer different from an arrangement position of the second electrode, and the plurality of second openings discontinuously surround the second electrode.

9. The method for manufacturing a semiconductor device according to claim 1,
wherein the inorganic insulating material contained in at least one insulating layer of the first insulating layer and the second insulating layer is silicon dioxide, silicon nitride, or silicon oxynitride.

10. A semiconductor device, comprising:
a first integrated circuit element including a first semiconductor substrate having a semiconductor element and a first wiring layer having a first insulating layer and a first electrode, the first wiring layer being provided on a surface of the first semiconductor substrate; and
a second integrated circuit element including a second semiconductor substrate having a semiconductor element and a second wiring layer having a second insulating layer and a second electrode, the second wiring layer being provided on a surface of the second semiconductor substrate,
wherein the first insulating layer of the first integrated circuit element and the second insulating layer of the second integrated circuit element are bonded to each other,
wherein the first electrode of the first integrated circuit element and the second electrode of the second integrated circuit element are bonded to each other,
wherein the first insulating layer contains an inorganic insulating material, and
wherein a plurality of first openings recessed toward the first semiconductor substrate from a first bonding surface bonded to the second insulating layer are provided at positions in the first insulating layer different from an arrangement position of the first electrode, and the plurality of first openings discontinuously surround the first electrode.

11. An integrated circuit element to be bonded to another integrated circuit element to manufacture a semiconductor device, comprising:
a semiconductor substrate having a first surface and a second surface, a semiconductor element being formed at least on the first surface or inside the semiconductor substrate; and
a wiring layer provided on the second surface of the semiconductor substrate,
wherein the wiring layer includes:
an inorganic insulating layer provided on the second surface of the semiconductor substrate; and
an electrode that is electrically connected to the semiconductor element of the semiconductor substrate and passes through the inorganic insulating layer to be exposed to an outside from the inorganic insulating layer, and
wherein a plurality of openings recessed toward the semiconductor substrate are provided at positions in the inorganic insulating layer different from an arrangement position of the electrode, and the plurality of openings discontinuously surround the electrode.

12. A method for manufacturing the integrated circuit element according to claim 11 to be bonded to another integrated circuit element to manufacture a semiconductor device, comprising:
providing a semiconductor substrate having a first surface and a second surface, a semiconductor element being formed at least on the first surface or inside the semiconductor substrate; and
forming a wiring layer on the second surface of the semiconductor substrate,
wherein the forming of the wiring layer includes:
forming an inorganic insulating layer on the second surface of the semiconductor substrate;
forming an electrode passing through the inorganic insulating layer so as to be electrically connected to the semiconductor element; and
forming a plurality of openings recessed toward the semiconductor substrate at positions in the inorganic insulating layer different from an arrangement position of the electrode, the plurality of openings discontinuously surrounding the electrode.

13. The method for manufacturing an integrated circuit element according to claim 12,
wherein, in the forming of the openings, the openings are formed by dry-etching the inorganic insulating layer.

14. The method for manufacturing an integrated circuit element according to claim 12,
wherein the forming of the openings is performed after the forming of the electrode.

15. The method for manufacturing an integrated circuit element according to claim 12,
wherein the forming of the electrode is performed after the forming of the openings.
